(19) United States
(12) Patent Application Publication
(10) Pub. No.: US 2019/0207134 A1
(43) Pub. Date: Jul. 4, 2019

(54) TFT AND METHOD FOR FABRICATING THE SAME

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventor: Huafei XIE, Shenzhen, Guangdong (CN)

(21) Appl. No.: 15/753,914

(22) PCT Filed: Jan. 24, 2018
(86) PCT No.: PCT/CN2018/074063

§ 371 Date: Nov. 6, 2018

(30) Foreign Application Priority Data
Dec. 28, 2017 (CN) 201711462014.5

(51) Int. Cl. H01L 51/05; H01L 51/00; H01L 27/28

(52) U.S. Cl. CPC H01L 51/0545; H01L 51/0018; H01L 51/0023; H01L 51/0016; H01L 51/105; H01L 27/283; H01L 51/0558; H01L 2251/308; H01L 51/0048

(57) ABSTRACT

Disclosed are provides a TFT and method for fabricating the same including: forming a first metal layer and a gate electrode; forming a gate insulating layer and a second metal layer on the substrate and the gate electrode, etching to form an active channel and a source electrode and a drain electrode, depositing to form an active layer in the active channel and on a surface of the second photoresist layer, lifting off the second photoresist layer, and keeping the active layer in the active channel; forming a passivation layer on the active layer, the source electrode and the drain electrode, and etching to form a through hole on the passivation layer; forming a third metal layer on the passivation layer and inside the through hole, etching to form an electrode electrically connected to either the source electrode or the drain electrode.

### RELATED APPLICATIONS

The present application is a National Phase of International Application Number PCT/CN2018/074063, filed Jan. 24, 2018, and claims the priority of China Application No. 201711462014.5, filed Dec. 28, 2017.

### FIELD OF THE DISCLOSURE

The disclosure relates to TFT, and particularly to a TFT and method for fabricating the same.

### BACKGROUND

Thin Film Transistor (TFT) is broadly used in flat display, flexible electronics, and touch sensing. The most popular TFT has amorphous silicon (a-Si) or poly silicon as its conductive channel. The a-Si TFT meets the requirements of large area and low to mid refresh rate of display and has good consistency. The poly silicon TFT has advantage of high mobility. However, these two transistors have their own limitations. The a-Si is very sensitive to light and the a-Si device has low mobility of carriers, so it cannot meet the requirement of high speed display whose frame rate is as high as 120 Hz or more. Although poly silicon TFT has the mobility high enough, its cost is high, its large-scale consistency is not good, and it is lack of flexibility and transparency which is fatal for transparent flexible device. The metal oxide TFT meets the requirement of display in both of mobility and transparency. However, the conventional metal oxide TFT is not stable, because it is sensitive to light, temperature, and vapor. Further, the metal oxide TFT is not stable under the stress of negative bias, so its threshold voltage drifts to the negative bias voltage.

Carbon Nanotube (CNT) has been noted and researched by the industry and the academia since being discovered in 1991. CNT shows great application possibility in the field of display, sensor, radio frequency circuit, flexible circuit, and etc. for its outstanding electricity performance, good thermal conductivity, and good mechanic strength. In CNT TFT, CNT is usually used as the material of the active layer.

The core of the TFT fabrication is the photolithography, and the photomask is the most important in the photolithography process. The photomask is a mother board for transforming the dedicate pattern and mainly used in the mass production of the array substrate process which is a necessary process in the TFT-LCD manufacture industry. The reduction of the number of the photomask can efficiently lead to the reduction of the equipment investment and the reduction of the manufacture period.

Hence, for the aforementioned problems, it is needed to provide a TFT and method for fabricating the same.

### SUMMARY

To overcome the deficiency of the conventional art, the disclosure is to provide a TFT and method for fabricating the same so as to improve the TFT fabricating process and to reduce the cost of manufacture.

For achieving the aforementioned purpose, one embodiment of the disclosure provides the following technical solution:

A method for fabricating thin film transistor (TFT), comprising:

a first photolithography process, forming a first metal layer on a substrate and etching to form a gate electrode with a first photomask and a first photoresist layer;

a second photolithography process, forming a gate insulating layer and a second metal layer on the substrate and the gate electrode, etching to form an active channel and a source electrode and a drain electrode with a second photomask and a second photoresist layer, wherein the source electrode and the drain electrode are at two opposite sides of the active channel, depositing to form an active layer in the active channel and on a surface of the second photoresist layer, lifting off the second photoresist layer, and keeping the active layer in the active channel;

a third photolithography process, forming a passivation layer on the active layer, the source electrode and the drain electrode, and etching to form a through hole on the passivation layer with a third photomask and a third photoresist layer; and

a fourth photolithography process, forming a third metal layer on the passivation layer and inside the through hole, etching the third metal layer with a fourth photomask and a fourth photoresist layer to form an electrode electrically connected to either the source electrode or the drain electrode.

In one further improvement of the disclosure, the first photolithography process comprises:

forming the first metal layer on the substrate;

forming the first photoresist layer on the first metal layer;

etching the first photoresist layer and the first metal layer with the first photomask; and

lifting off the first photoresist layer and then forming the gate electrode on the substrate.

In one further improvement of the disclosure, the second photolithography process comprises:

forming the gate insulating layer on the substrate and the gate electrode;

forming the second metal layer on the gate insulating layer;

forming the second photoresist layer on the second metal layer;

etching an upper region on the gate electrode to the gate insulating layer with the second photomask to form the active channel and the source electrode and the drain electrode, wherein the source electrode and the drain electrode are at two opposite sides of the active channel;

depositing the active layer on the surface of the second photoresist layer and in the active channel; and

lifting off the second photoresist layer and the active layer thereon and keeping the active layer in the active channel.

In one further improvement of the disclosure, the third photolithography process comprises:

forming the passivation layer on the active layer, the source electrode and the drain electrode;

forming the third photoresist layer on the passivation layer;

etching an upper region on the source electrode with the third photomask to the source electrode or an upper region on the drain electrode with the third photomask to the drain electrode; and

lifting off the third photoresist layer and etching the passivation layer to form the through hole.

In one further improvement of the disclosure, the fourth photolithography process comprises:

forming the third metal layer on the passivation layer and inside the through hole;

forming the fourth photoresist layer on the third metal layer;

etching the third metal layer adjacent to the through hole with the fourth photomask and at least keeping the third metal layer inside the through hole; and

lifting off the fourth photoresist layer to form the electrode electrically connected to either the source electrode or the drain electrode.

In one further improvement of the disclosure, the active layer is a carbon nanotube active layer.

In one further improvement of the disclosure, the method further comprises:

performing a washing process before each of the photolithography processes.

Another embodiment of the disclosure provides the following technical solution:

a TFT comprising:

a substrate;

a gate electrode on the substrate;

a gate insulating layer on the substrate and the gate electrode;

a source electrode and a drain electrode both on the gate insulating layer;

an active channel between the source electrode and the drain electrode;

an active layer in the active channel;

a passivation layer on the source electrode, the drain electrode and the active layer, wherein the passivation layer has a through hole penetrating the passivation layer; and

an electrode on the passivation layer and penetrating the through hole, electrically connected to either the source electrode or the drain electrode.

In one further improvement of the disclosure, the active layer is a carbon nanotube active layer.

In one further improvement of the disclosure, the TFT is a bottom gate TFT.

Only four photomask and corresponding photolithography processes are needed for fabricating the TFT in the disclosure. The active channel is directly fabricated when the photoresist is lifted off with the lift off process in the second photolithography process, so the fabrication process is upgraded, the number of photomask is reduced, and the fabrication cost is reduced.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a flowchart of the method for fabricating TFT in the disclosure; and

FIG. 2-FIG. 20 are drawings of TFT fabricating process in one embodiment of the disclosure, wherein FIG. 20 is the structural schematic of TFT.

### DETAILED DESCRIPTION OF PREFERRED EMBODIMENTS

In order to understand the above objectives, features and advantages of the present disclosure more clearly, the present disclosure is described in detail below with references to the accompanying drawings and specific embodiments.

The term in the following expressing the spatial relative position such as on, above, upper, below, under, lower, and etc. is for illustrating the relationship between a unit and another unit or a feature and another feature in the drawings.

The term of the spatial relative position may include the positions of the apparatus in use other than the shown position. For example, if the apparatus in the drawing is flipped, the unit illustrated under or below the other unit would be on or above the other unit. Hence, the exemplary term below may include the two positions such as above and below. The apparatus may be oriented in another way such as being rotated with 90 degree or other orientation, the spatial descriptions in the following are correspondingly explained.

With the variation of the TFT structure and the improvement of the fabricating process, the number of the photomasks used in the TFT fabricating process decreases simultaneously. The TFT devices in early age usually utilized the back channel protection structure and the TFT array substrate was generally implemented with seven photomasks or six photomasks. Ten years ago, the back channel etching TFT device was in production with the five photomask process, and then the four photomask process was developed and applicable in the fifth generation production line so the time consumed and cost of the TFT LCD fabrication was largely reduced. From the seven photomask process to the six photomask process, the core process is that the SiNₓ protection layer on the a-Si:H active layer is removed and the gate insulating layer, the a-Si:H layer, the n+ layer, and the a-Si ohmic contact layer are continuously epitaxial so only one photomask is needed for forming the active layer Si island and the number of the photomasks is reduced. The change from the back channel protection device to the back channel etching device was therefore achieved and it is the generally utilized device in the industry.

As to the five photomask process, as shown in table 1, the through hole connecting the drain electrode and the ITO pixel electrode and the through hole connecting the routing pad in the gate electrode routing region and the external driving circuit routing are patterned in one step on the basis of the six photomask process so that one photomask process is saved. As to the four photomask process, the grayscale or the semi-scale photography process is utilized on the basis of the five photomask process. The active layer photomask and the source drain electrode photomask are integrated into one photomask, the exposure for different region is achieved by controlling the ratio between the channel region and the other regions so as to achieve the functionality of the original active photomask and the S/D photomask. That is, the effect of the two photomasks is achieved by one photomask.

TABLE 1
Five photomask process

| first | second | third | fourth | fifth |
|---|---|---|---|---|
| photomask | photomask | photomask | photomask | photomask |
| gate | active layer | source/drain | through | ITO |
| electrode | | electrode film | hole | |
| washing | washing | Washing | washing | washing |
| sputtering | depositing | sputtering | depositing | sputtering |
| metal | insulating layer | metal | protection | ITO |
| | and active layer | | layer | |
| photomask | photomask | photomask | photomask | photomask |
| exposure | exposure | exposure | exposure | exposure |
| etching | etching active | etching | etching | etching ITO |
| gate | layer | source/drain | through hole | |
| electrode | | electrode | | |
| lifting off | lifting off | N+ a-Si | lifting off | lifting off |
| photoresist | positive | etching | positive | positive |
| | photoresist | | photoresist | photoresist |
| | | lifting off | | |
| | | positive | | |
| | | photoresist | | |

TABLE 2
conventional four photomask process
Conventional four photomask process
(grayscale exposure process)

| first | second | third | fourth |
|---|---|---|---|
| photomask | photomask | photomask | photomask |
| gate | grayscale | through hole | ITO |
| electrode | | | |
| washing | washing | washing | Washing |
| sputtering | depositing | depositing | sputtering ITO |
| metal | insulating layer | protection layer | |
| | and active layer | | |
| photomask | Washing | photomask | photomask |
| exposure | | exposure | exposure |
| etching gate | sputtering metal | etching through | etching ITO |
| electrode | | hole | |
| lifting off | grayscale | lifting off positive | lifting off |
| negative | exposure | photoresist | positive |
| photoresist | | | photoresist |
| | etching | | |
| | source/drain | | |
| | electrode | | |
| | grayscale region | | |
| | etching | | |
| | (N+ a-Si etching) | | |
| | lifting off positive | | |
| | photoresist | | |

This disclosure provides a TFT includes:

a substrate;

a gate electrode on the substrate;

the gate insulating layer on the substrate and the gate electrode;

the source electrode and the drain electrode both on the gate insulating layer, and the active channel between the source electrode and the drain electrode;

the active layer in the active channel;

the passivation layer on the source electrode, the drain electrode and the active layer, wherein the passivation layer has at least one through hole penetrating the passivation layer;

the electrode on the passivation layer and penetrating the through hole, wherein the electrode is electrically connected to either the source electrode or the drain electrode.

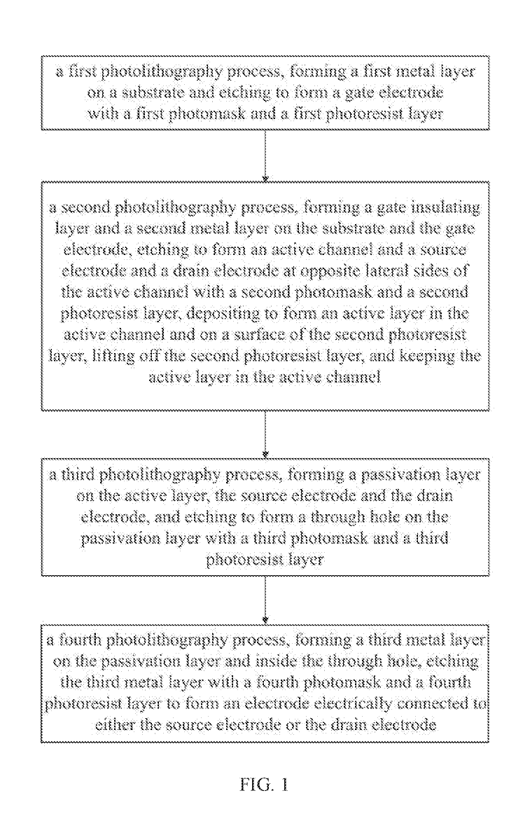

As shown in FIG. 1 and table 3, the disclosure provides a method for fabricating a TFT, the method including the following steps:

a first photolithography process, forming a first metal layer on a substrate and etching to form a gate electrode with a first photomask and a first photoresist layer;

a second photolithography process, forming a gate insulating layer and a second metal layer on the substrate and the gate electrode, etching to form an active channel and a source electrode and a drain electrode with a second photomask and a second photoresist layer, wherein the source electrode and the drain electrode are at two opposite sides of the active channel, depositing to form an active layer in the active channel and on a surface of the second photoresist layer, lifting off the second photoresist layer, and keeping the active layer in the active channel;

a third photolithography process, forming a passivation layer on the active layer, the source electrode and the drain electrode, and etching to form a through hole on the passivation layer with a third photomask and a third photoresist layer, and

a fourth photolithography process, forming a third metal layer on the passivation layer and inside the through hole, etching the third metal layer with a fourth photomask and a fourth photoresist layer to form an electrode electrically connected to either the source electrode or the drain electrode.

TABLE 3
the four photomask process in the disclosure
Four photomask process in the disclosure

| | second | third | fourth |
|---|---|---|---|
| first photomask | photomask | photomask | photomask |
| gate electrode | partial lifting off | through | ITO |
| | | hole | |
| washing | washing | washing | washing |
| sputtering metal | sputtering | depositing | Sputtering ITO |
| | metal | protection | |
| | | layer | |
| photomask | washing | photomask | photomask |
| exposure | | exposure | exposure |
| etching gate | photomask | etching | etching ITO |
| electrode | exposure | through hole | |
| lifting off negative | etching | lifting off | lifting off positive |
| photoresist | source/drain | positive | photoresist |
| | electrode | photoresist | |
| | Solution | | |
| | depositing CNT | | |
| | active layer | | |
| | lifting off | | |
| | negative | | |
| | photoresist and | | |
| | out-of-channel | | |
| | CNT | | |
| | lifting off | | |
| | negative | | |
| | photoresist | | |

In the second photolithography process of the disclosure, the photoresist layer on the second metal layer is taken as the active layer photoresist and the lift off process is performed to fabricate the active layer. The photoresist stripper removes the photoresist as well as pattern the active layer so as to fabricate the active channel directly.

In the following, the disclosure is further illustrated with embodiments.

As shown in FIG. 19, a TFT in one embodiment of the disclosure includes:

a substrate 10;

a gate electrode 21 on the substrate 10;

a gate insulating layer 30 on the substrate 10 and the gate electrode 21;

a source electrode 41 and a drain electrode 42 on the gate insulating layer 30, and an active channel 51 between the source electrode 41 and the drain electrode 42;

an active layer 50 in the active channel 51;

a passivation layer 60 on the source electrode 41, the drain electrode 42 and the active layer 50, wherein the passivation layer 60 has a through hole 71;

an electrode 72 on the passivation layer 60 and penetrating the through hole 71, wherein the electrode 72 is electrically connected to the source electrode 41.

In another embodiment, the electrode 72 is disposed above the drain electrode 42 and electrically connected to the drain electrode 42 via the through hole 71.

The TFT in this embodiment is a bottom gate TFT, and the active layer 50 is a carbon nanotube (CNT) active layer. In another embodiment, the material of the active layer is graphene, black phosphorus, and etc.

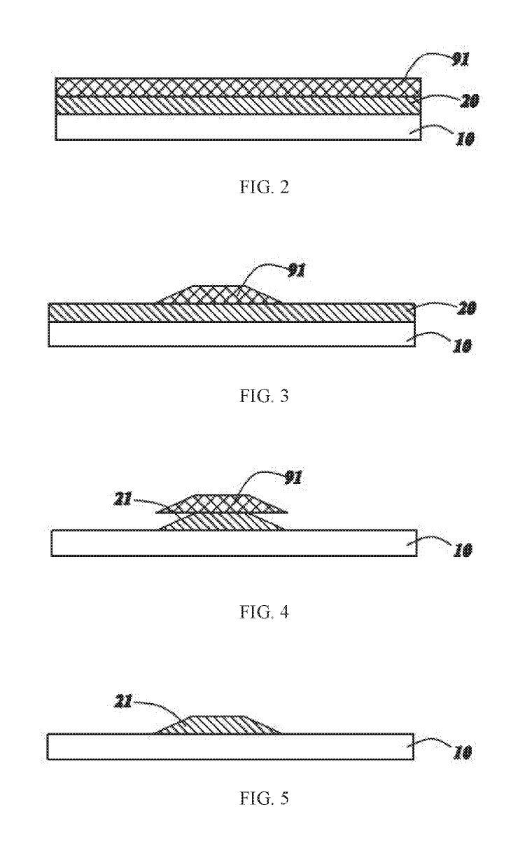

Explicitly, the method for fabricating TFT in the embodiment is illustrated in detail with FIGS. 2-19.

The first photolithography process includes:

As shown in FIG. 2, forming the first metal layer 20 on the substrate 10;

Then, forming the first photoresist layer 91 on the first metal layer 20;

As shown in FIG. 3 and FIG. 4, etching the first photoresist layer 91 and the first metal layer 20 with the first photoresist layer 91;

As shown in FIG. 5, lifting off the first photoresist layer 91 and then forming the gate electrode 21 on the substrate 10.

The second photolithography process includes:

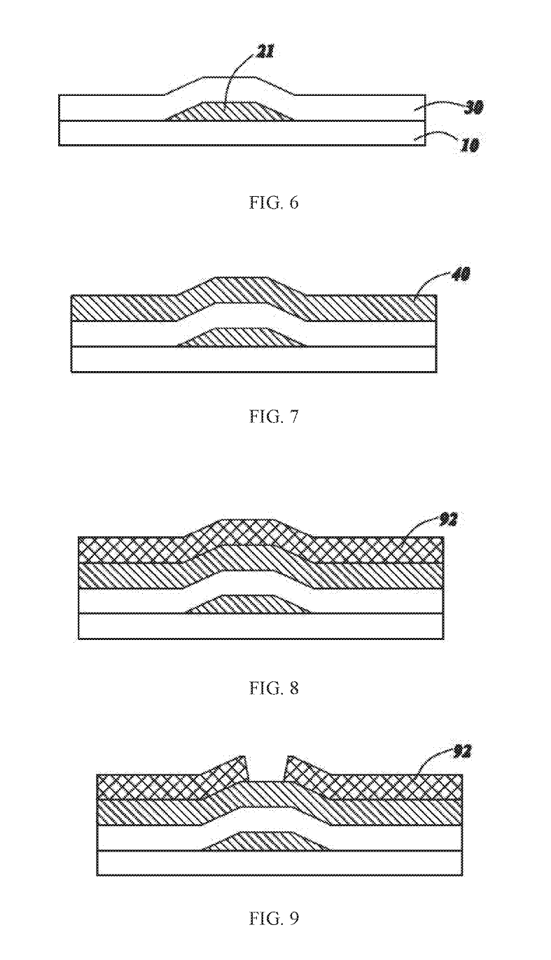

As shown in FIG. 6, forming the gate insulating layer 30 on the substrate 10 and the gate electrode 21;

As shown in FIG. 7, forming the second metal layer 40 on the gate insulating layer 30;

As shown in FIG. 8, forming the second photoresist layer 92 on the second metal layer 40;

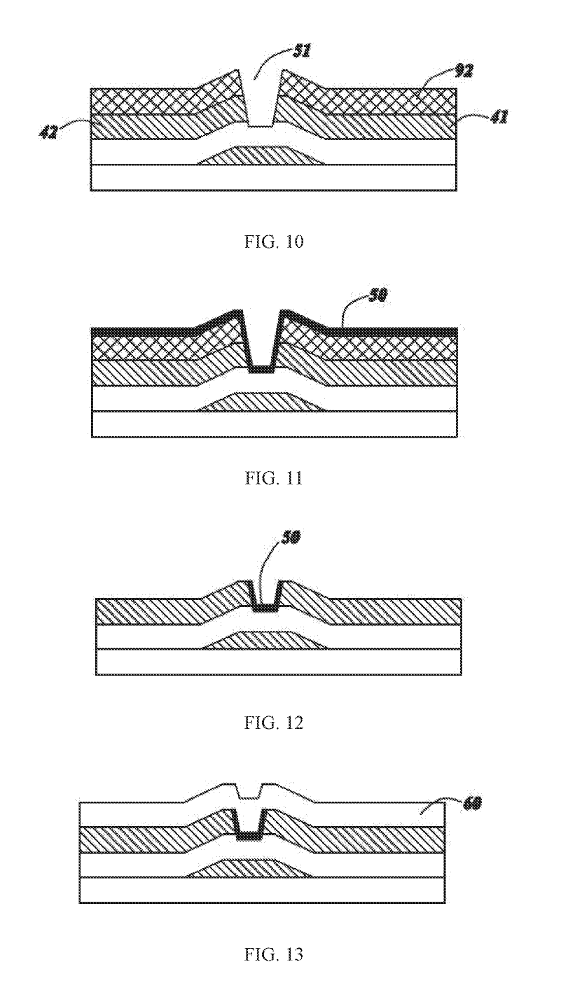

As shown in FIG. 9 and FIG. 10, etching the upper region on the gate electrode to the gate insulating layer 30 with the second photomask so as to form the active channel 51 and the source electrode 41 and the drain electrode 42, wherein the source electrode and the drain electrode are at two opposite sides of the active channel;

As shown in FIG. 11, depositing the active layer 50 in the active channel 51 and on the surface of the second photoresist layer 92;

As shown in FIG. 12, lifting off the second photoresist layer 92 and the active layer thereon and keeping the active layer 50 in the active channel 51.

The third photolithography process includes:

As shown in FIG. 13, forming the passivation layer 60 on the active layer 50, the source electrode 41 and the drain electrode 42;

As shown in FIG. 14, forming the third photoresist layer 93 on the passivation layer;

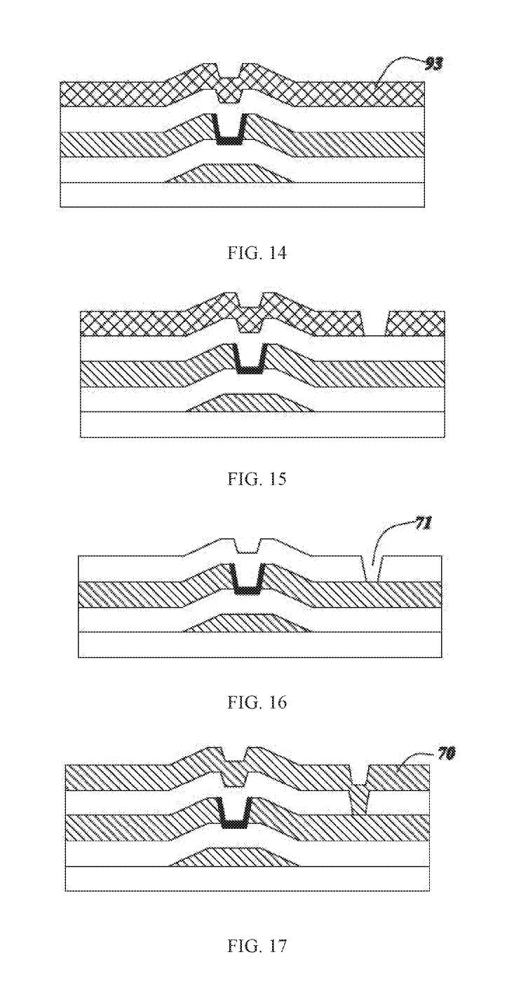

As shown in FIG. 15 and FIG. 16, etching the upper region on the source electrode to the source electrode with the third photomask;

Then lifting off the third photoresist layer 93 so as to form the through hole 71 on the passivation layer 60.

The fourth photolithography process includes:

As shown in FIG. 17, forming the third metal layer 70 on the passivation layer 60 and inside the through hole 71;

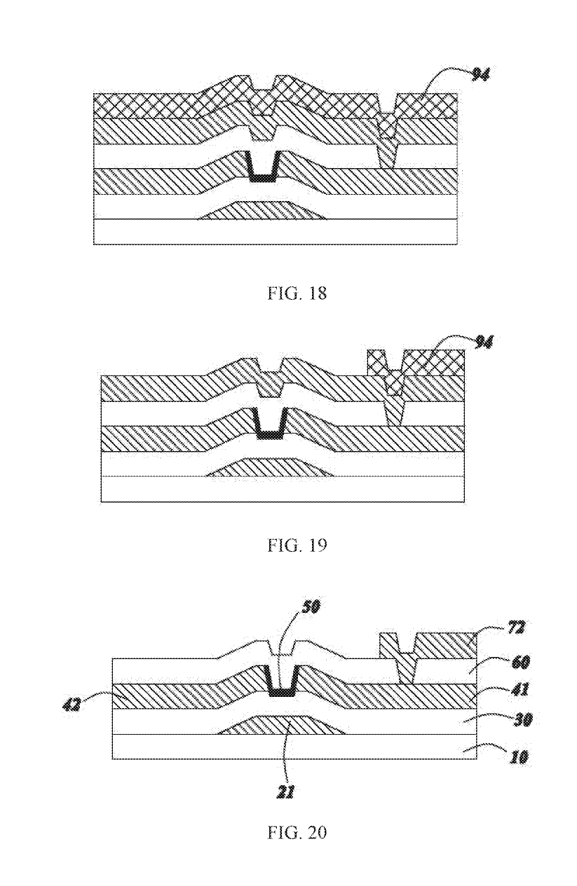

As shown in FIG. 18, forming the fourth photoresist 94 on the third metal layer 70;

As shown in FIG. 19, etching the third metal layer 70 adjacent to the through hole 71 with the fourth photomask and at least keeping the third metal layer 70 inside the through hole;

As shown in FIG. 20, lifting off the fourth photoresist layer 94 to form the electrode 72 electrically connected to the source electrode 41.

The thickness and the area of the film layer in the drawings do not reflect the ratio of the portions of the TFT and the array substrate. The drawings are for exemplarily illustrating the disclosure.

The substrate 10 may be a flexible substrate such as a polyethylene terephthalate (PET) substrate, a polyimide (PI) substrate, and etc. The substrate 10 surely may be rigid substrate such as glass substrate, silicon oxide substrate silicon nitride substrate, and etc.

In one embodiment of the disclosure, the metal layer may be deposited by sputtering and form the gate electrode 21, the source electrode 41 and the drain electrode 42 by patterning. Further, the material of the metal layer may be metallic material such as Mo, Al, or Cr, alloy material, or other conductive composite.

The passivation layer 60 may be form with plasma-enhanced chemical vapor deposition (PECVD) and the material thereof may be SiO2, SiNₓ, or equivalent insulating materials.

The electrode 72 may be indium tin oxide (ITO) electrode but is not limited thereto.

The gate insulating layer 30 may be deposited by PECVD, and its material may be insulating material such as silicon oxide (SiOₓ) or silicon nitride (SiNₓ).

Coating a semiconductor CNT thin film on the surface of the silicon oxide (SiOₓ) or on the surface of the silicon nitride (SiNₓ) with the solution process such as spin-coating, dip-coating, and etc.;

In an exemplary embodiment, the carbon nanotube (CNT) material has high mobility, so the CNT material may be used for fabricating the active layer 50, but the disclosure does not limit thereto. The active layer 50, except the CNT material, may use one-dimension material such as silicon nanoline or III-V nanoline, and the semiconductor material with overlapping structure such as X,Y structure.

The aforementioned CNT may be fabricated with the conventional CNT fabrication method. For example, the electric arc process, or heat plasma process or laser abalation process, may be used for fabricating the CNT powders. The CNT powders are mixed with toluene solution with polymers, and then being dispersed, centrifuged, filtered and re-dispersed so as to obtain semiconductive CNT solution. The CNT solution is used for making the active layer 50 of the TFT in the embodiment of the disclosure in advance.

From the aforementioned technical solutions, only four photomask and corresponding photolithography processes are needed for fabricating the TFT in the disclosure. The active channel is directly fabricated when the photoresist is lifted off with the lift off process in the second photolithography process, so the fabrication process is upgraded, the number of photomask is reduced, and the fabrication cost is reduced.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A method for fabricating TFTs, comprising:
a first photolithography process, forming a first metal layer on a substrate and etching to form a gate electrode with a first photomask and a first photoresist layer,
a second photolithography process, forming a gate insulating layer and a second metal layer on the substrate and the gate electrode, etching to form an active channel and a source electrode and a drain electrode with a second photomask and a second photoresist layer, wherein the source electrode and the drain electrode are at two opposite sides of the active channel, depositing to form an active layer in the active channel and on a surface of the second photoresist layer, lifting off the second photoresist layer, and keeping the active layer in the active channel;
a third photolithography process, forming a passivation layer on the active layer, the source electrode and the drain electrode, and etching to form a through hole on the passivation layer with a third photomask and a third photoresist layer; and
a fourth photolithography process, forming a third metal layer on the passivation layer and inside the through hole, etching the third metal layer with a fourth photomask and a fourth photoresist layer to form an electrode electrically connected to either the source electrode or the drain electrode.

2. The method as claimed in claim 1, wherein the first photolithography process comprises:
forming the first metal layer on the substrate;
forming the first photoresist layer on the first metal layer;
etching the first photoresist layer and the first metal layer with the first photomask; and
lifting off the first photoresist layer and then forming the gate electrode on the substrate.

3. The method as claimed in claim 1, wherein the second photolithography process comprises:
forming the gate insulating layer on the substrate and the gate electrode;
forming the second metal layer on the gate insulating layer,
forming the second photoresist layer on the second metal layer;
etching an upper region on the gate electrode to the gate insulating layer with the second photomask to form the active channel and the source electrode and the drain electrode, wherein the source electrode and the drain electrode are at two opposite sides of the active channel;
depositing the active layer on the surface of the second photoresist layer and in the active channel; and
lifting off the second photoresist layer and the active layer thereon and keeping the active layer in the active channel.

4. The method as claimed in claim 1, wherein the third photolithography process comprises:
forming the passivation layer on the active layer, the source electrode and the drain electrode;
forming the third photoresist layer on the passivation layer;
etching an upper region on the source electrode with the third photomask to the source electrode or an upper region on the drain electrode with the third photomask to the drain electrode; and
lifting off the third photoresist layer and etching the passivation layer to form the through hole.

5. The method as claimed in claim 1, wherein the fourth photolithography process comprises:
forming the third metal layer on the passivation layer and inside the through hole;
forming the fourth photoresist layer on the third metal layer;
etching the third metal layer adjacent to the through hole with the fourth photomask and at least keeping the third metal layer inside the through hole; and
lifting off the fourth photoresist layer to form the electrode electrically connected to either the source electrode or the drain electrode.

6. The method as claimed in claim 2, wherein the second photolithography process comprises:
forming the gate insulating layer on the substrate and the gate electrode;
forming the second metal layer on the gate insulating layer;
forming the second photoresist layer on the second metal layer,
etching an upper region on the gate electrode to the gate insulating layer with the second photomask to form the active channel and the source electrode and the drain electrode, wherein the source electrode and the drain electrode are at two opposite sides of the active channel;
depositing the active layer on the surface of the second photoresist layer and in the active channel; and
lifting off the second photoresist layer and the active layer thereon and keeping the active layer in the active channel.

7. The method as claimed in claim 2, wherein the third photolithography process comprises:
forming the passivation layer on the active layer, the source electrode and the drain electrode;
forming the third photoresist layer on the passivation layer,
etching an upper region on the source electrode with the third photomask to the source electrode or an upper region on the drain electrode with the third photomask to the drain electrode; and
lifting off the third photoresist layer and etching the passivation layer to form the through hole.

8. The method as claimed in claim 2, wherein the fourth photolithography process comprises:
forming the third metal layer on the passivation layer and inside the through hole;
forming the fourth photoresist layer on the third metal layer;
etching the third metal layer adjacent to the through hole with the fourth photomask and at least keeping the third metal layer inside the through hole; and
lifting off the fourth photoresist layer to form the electrode electrically connected to either the source electrode or the drain electrode.

9. The method as claimed in claim 6, wherein the third photolithography process comprises:
forming the passivation layer on the active layer, the source electrode and the drain electrode;
forming the third photoresist layer on the passivation layer,
etching an upper region on the source electrode with the third photomask to the source electrode or an upper region on the drain electrode with the third photomask to the drain electrode; and
lifting off the third photoresist layer and etching the passivation layer to form the through hole.

10. The method as claimed in claim 9, wherein the fourth photolithography process comprises:
forming the third metal layer on the passivation layer and inside the through hole;
forming the fourth photoresist layer on the third metal layer;
etching the third metal layer adjacent to the through hole with the fourth photomask and at least keeping the third metal layer inside the through hole; and
lifting off the fourth photoresist layer to form the electrode electrically connected to either the source electrode or the drain electrode.

11. The method as claimed in claim 1, wherein the active layer is a carbon nanotube active layer.

12. The method in claim 1, further comprising:
performing a washing process before each of the photolithography processes.

13. A TFT fabricated by a method comprising:
a first photolithography process, forming a first metal layer on a substrate and etching to form a gate electrode with a first photomask and a first photoresist layer;
a second photolithography process, forming a gate insulating layer and a second metal layer on the substrate and the gate electrode, etching to form an active channel and a source electrode and a drain electrode with a second photomask and a second photoresist layer, wherein the source electrode and the drain electrode are at two opposite sides of the active channel, depositing to form an active layer in the active channel and on a surface of the second photoresist layer, lifting off the second photoresist layer, and keeping the active layer in the active channel;
a third photolithography process, forming a passivation layer on the active layer, the source electrode and the drain electrode, and etching to form a through hole on the passivation layer with a third photomask and a third photoresist layer; and
a fourth photolithography process, forming a third metal layer on the passivation layer and inside the through hole, etching the third metal layer with a fourth photomask and a fourth photoresist layer to form an electrode electrically connected to either the source electrode or the drain electrode;
wherein the TFT comprising:
the substrate;
the gate electrode on the substrate;
the gate insulating layer on the substrate and the gate electrode;
the source electrode and the drain electrode both on the gate insulating layer;
the active channel between the source electrode and the drain electrode;
the active layer in the active channel;
the passivation layer on the source electrode, the drain electrode and the active layer, wherein the passivation layer has a through hole penetrating the passivation layer; and
the electrode on the passivation layer and penetrating the through hole, electrically connected to either the source electrode or the drain electrode.

14. The TFT as claimed in claim 13, wherein the active layer is a carbon nanotube active layer.

15. The TFT as claimed in claim 13, wherein the TFT is a bottom gate TFT.

16. The TFT as claimed in claim 13, wherein the first photolithography process comprises:
forming the first metal layer on the substrate;
forming the first photoresist layer on the first metal layer;
etching the first photoresist layer and the first metal layer with the first photomask; and
lifting off the first photoresist layer and then forming the gate electrode on the substrate.

17. The TFT as claimed in claim 16, wherein the second photolithography process comprises:
forming the gate insulating layer on the substrate and the gate electrode;
forming the second metal layer on the gate insulating layer;
forming the second photoresist layer on the second metal layer;
etching an upper region on the gate electrode to the gate insulating layer with the second photomask to form the active channel and the source electrode and the drain electrode, wherein the source electrode and the drain electrode are at two opposite sides of the active channel;
depositing the active layer on the surface of the second photoresist layer and in the active channel; and
lifting off the second photoresist layer and the active layer thereon and keeping the active layer in the active channel.

18. The TFT as claimed in claim 17, wherein the third photolithography process comprises:
forming the passivation layer on the active layer, the source electrode and the drain electrode;
forming the third photoresist layer on the passivation layer;
etching an upper region on the source electrode with the third photomask to the source electrode or an upper region on the drain electrode with the third photomask to the drain electrode; and
lifting off the third photoresist layer and etching the passivation layer to form the through hole.

19. The TFT as claimed in claim 18, wherein the fourth photolithography process comprises:
forming the third metal layer on the passivation layer and inside the through hole;
forming the fourth photoresist layer on the third metal layer;
etching the third metal layer adjacent to the through hole with the fourth photomask and at least keeping the third metal layer inside the through hole; and
lifting off the fourth photoresist layer to form the electrode electrically connected to either the source electrode or the drain electrode.
